(19) United States
(12) Patent Application Publication
(10) Pub. No.: US 2024/0105851 A1
(43) Pub. Date: Mar. 28, 2024

(54) SEMICONDUCTOR DEVICE STRUCTURE AND METHOD FOR FORMING THE SAME

(71) Applicant: Taiwan Semiconductor Manufacturing Company, Ltd., Hsinchu (TW)

(72) Inventors: Jiefeng Jeff LIN, Hsinchu (TW); Chen-Hua TSAI, Hsinchu County (TW); Shyh-Horng YANG, Hsinchu (TW)

(73) Assignee: Taiwan Semiconductor Manufacturing Company, Ltd., Hsinchu (TW)

(21) Appl. No.: 18/153,911

(22) Filed: Jan. 12, 2023

Related U.S. Application Data
(60) Provisional application No. 63/410,366, filed on Sep. 27, 2022.

(51) Int. Cl. H01L 29/78; H01L 21/265; H01L 21/266; H01L 29/66

(52) U.S. Cl. CPC H01L 29/7855; H01L 21/26506; H01L 21/266; H01L 29/66795; H01L 2029/7858

(57) ABSTRACT

A method for forming a semiconductor device structure is provided. The method includes forming a first well region and a second well region in a substrate. The method includes forming a third well region in the substrate and between the first well region and the second well region. The method includes forming a deep well region in the substrate and under the first well region and the third well region. The method includes partially removing the substrate to form a first fin, a second fin, and a third fin in the first well region, the second well region, and the third well region respectively. The method includes forming a first epitaxial structure, a second epitaxial structure, and a third epitaxial structure in the first recess, the second recess, and the third recess respectively.

### PRIORITY CLAIM AND CROSS-REFERENCE

This application claims the benefit of U.S. Provisional Application No. 63/410,366, filed on Sep. 27, 2022, and entitled “SEMICONDUCTOR DEVICE STRUCTURE AND METHOD FOR FORMING THE SAME”, the entirety of which is incorporated by reference herein.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs.

In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1S are top views of various stages of a process for forming a semiconductor device structure, in accordance with some embodiments.

FIG. 1A-1 is a perspective view of the semiconductor device structure of FIG. 1A, in accordance with some embodiments.

FIGS. 1B-1 to 1H-1 are cross-sectional views illustrating the semiconductor device structure along a sectional line I-I′ in FIGS. 1B-1H, in accordance with some embodiments.

FIG. 1H-2 is a cross-sectional view illustrating the semiconductor device structure along a sectional line II-II′ in FIG. 1H, in accordance with some embodiments.

FIG. 1H-3 is a perspective view of the semiconductor device structure of FIG. 1H, in accordance with some embodiments.

FIG. 1H-4 is a perspective view of a portion of the semiconductor device structure of FIG. 1H-3, in accordance with some embodiments.

FIGS. 1I-1 to 1K-1 are perspective views of a portion of the semiconductor device structure in FIGS. 1I-1K, in accordance with some embodiments.

FIGS. 1L-1 to 1S-1 are perspective views of a portion of the semiconductor device structure in FIGS. 1L-1S, in accordance with some embodiments.

FIG. 1Q-2 is a cross-sectional view illustrating the semiconductor device structure along a sectional line I-I′ in FIG. 1Q, in accordance with some embodiments.

FIG. 1R-2 is a cross-sectional view illustrating the semiconductor device structure along a sectional line I-I′ in FIG. 1R, in accordance with some embodiments.

FIG. 1S-2 is a cross-sectional view illustrating the semiconductor device structure along a sectional line I-I′ in FIG. 1S, in accordance with some embodiments.

FIG. 1S-3 is a cross-sectional view illustrating the semiconductor device structure along a sectional line II-IF in FIG. 15, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art. For example, the term “substantially” may also relate to 90% of what is specified or higher, such as 95% of what is specified or higher, especially 99% of what is specified or higher, including 100% of what is specified, though the present invention is not limited thereto. Furthermore, terms such as “substantially parallel” or “substantially perpendicular” may be interpreted as not to exclude insignificant deviation from the specified arrangement and may include for example deviations of up to 10°. The word “substantially” does not exclude “completely” e.g. a composition which is “substantially free” from Y may be completely free from Y.

The term “about” may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10% of what is specified, though the present invention is not limited thereto. The term “about” in relation to a numerical value x may mean x ±5 or 10% of what is specified, though the present invention is not limited thereto.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

Embodiments of the disclosure form a semiconductor device structure with FinFETs. The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. Source/drain structure(s) may refer to a source or a drain, individually or collectively dependent upon the context.

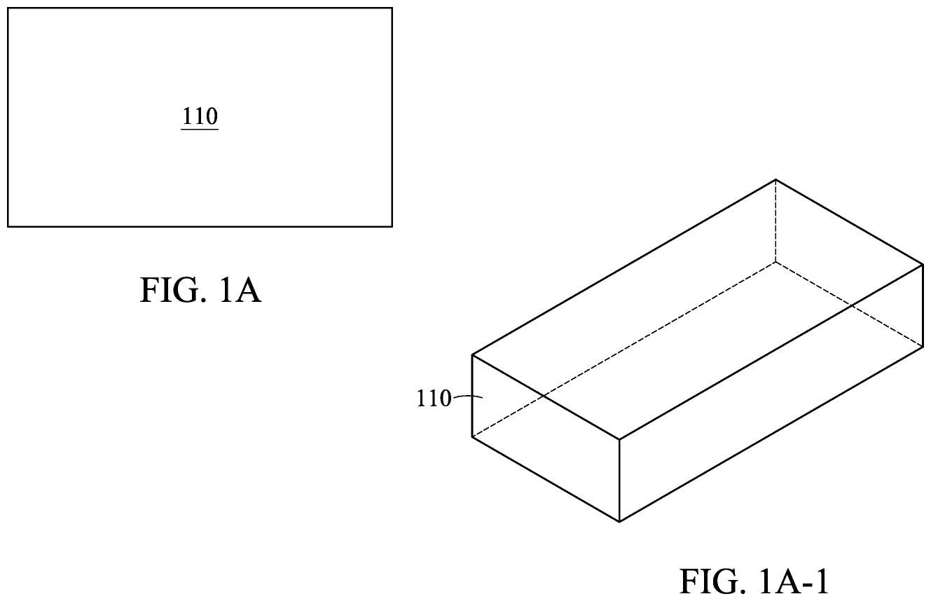

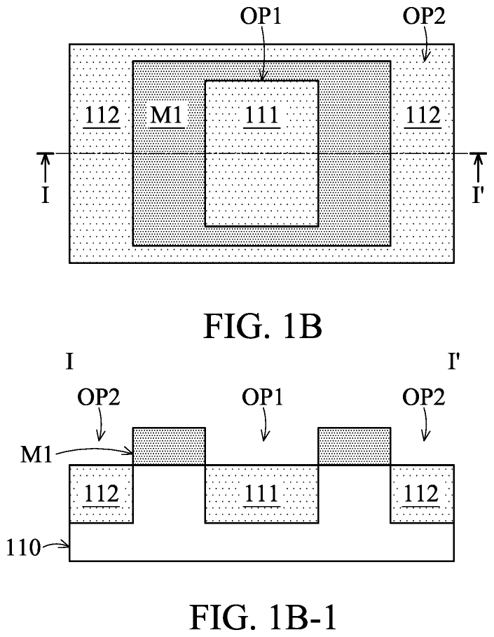

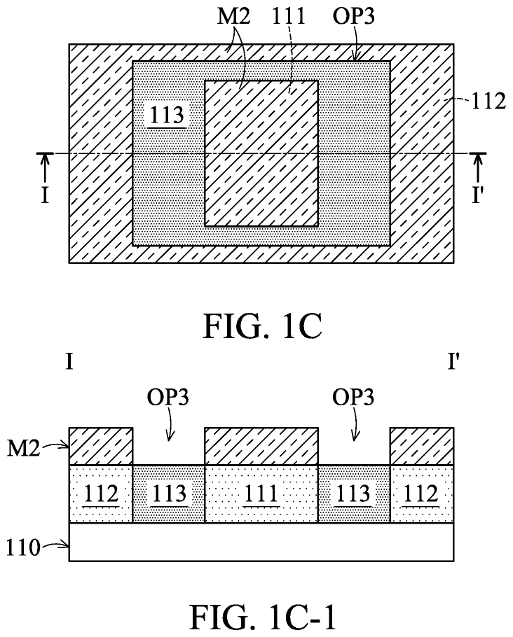

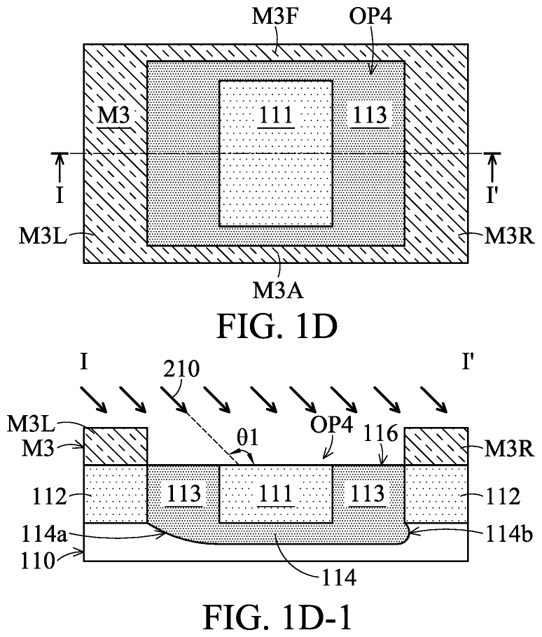

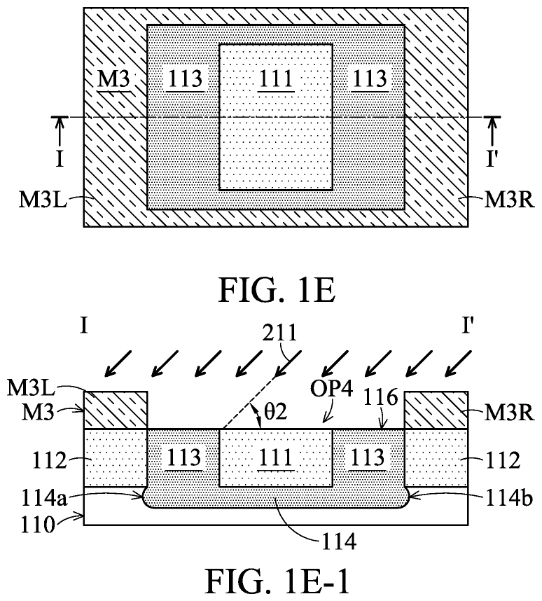

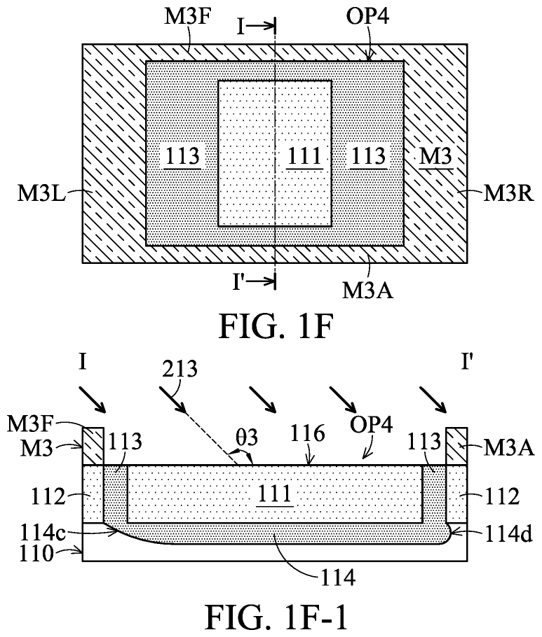

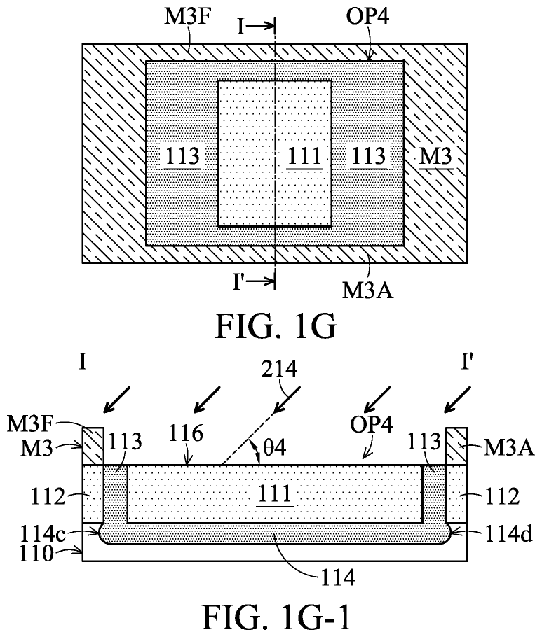

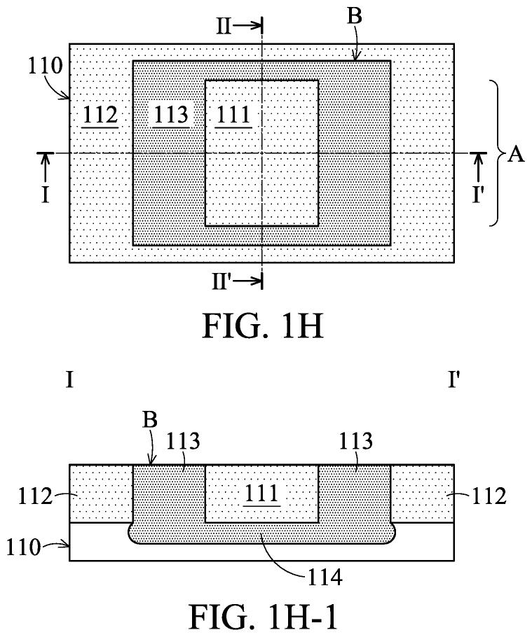

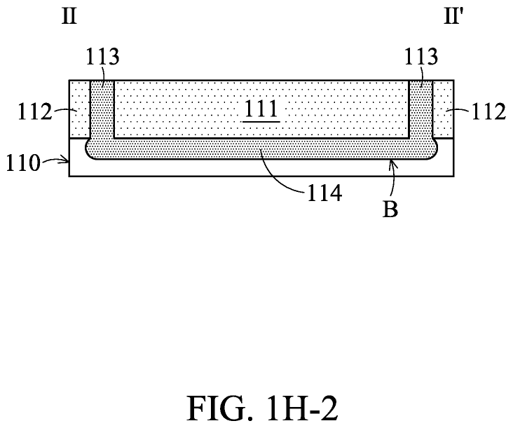

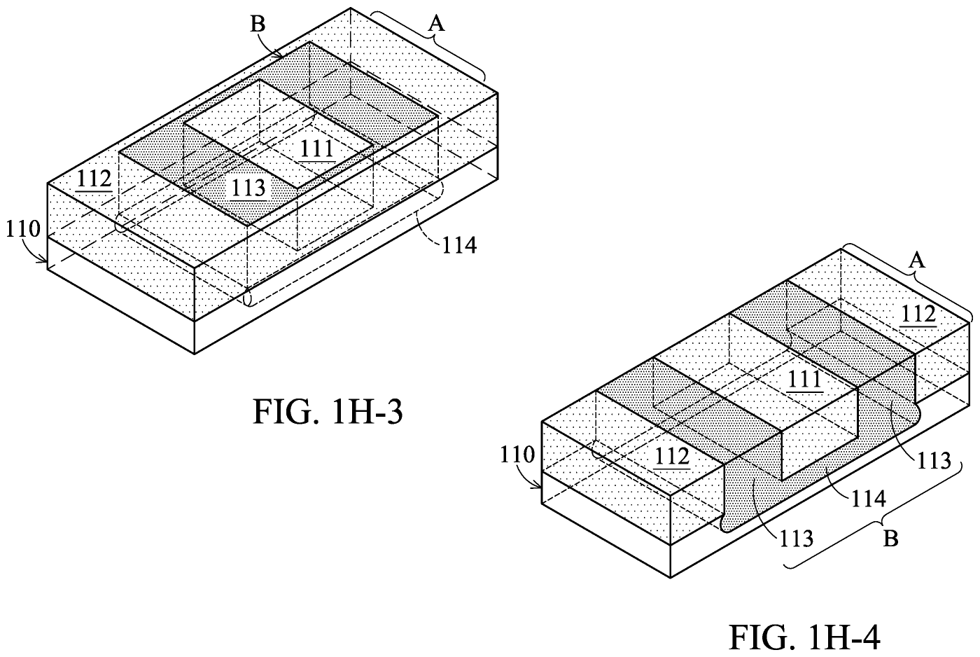

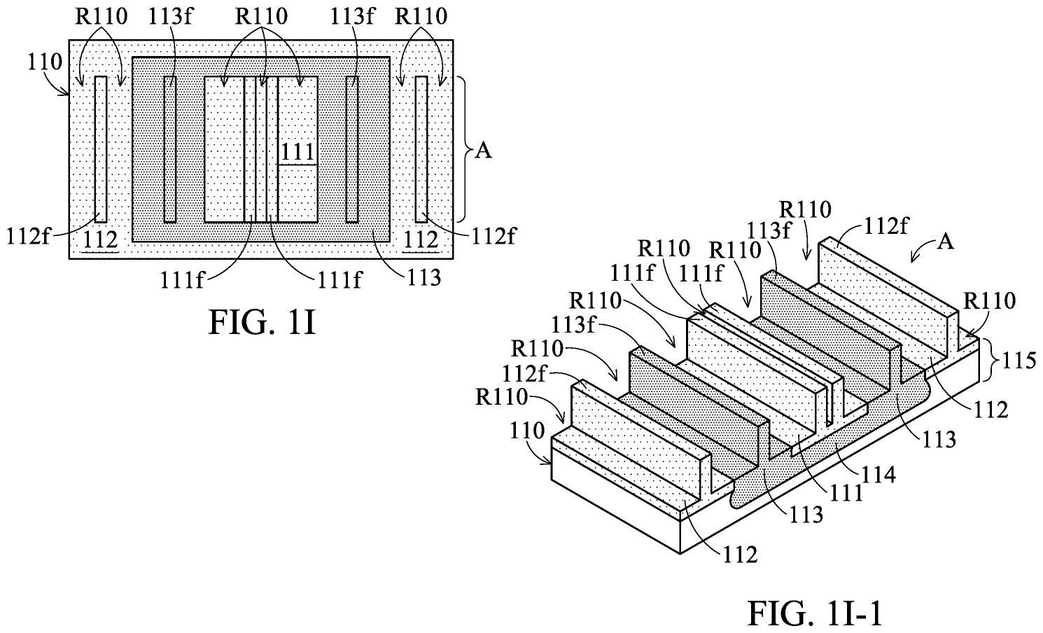

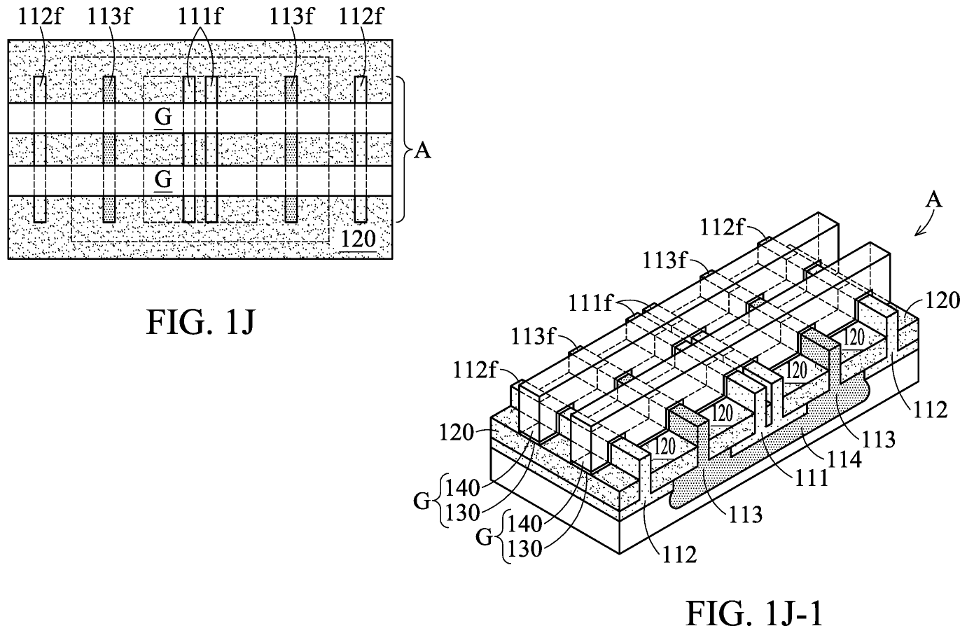

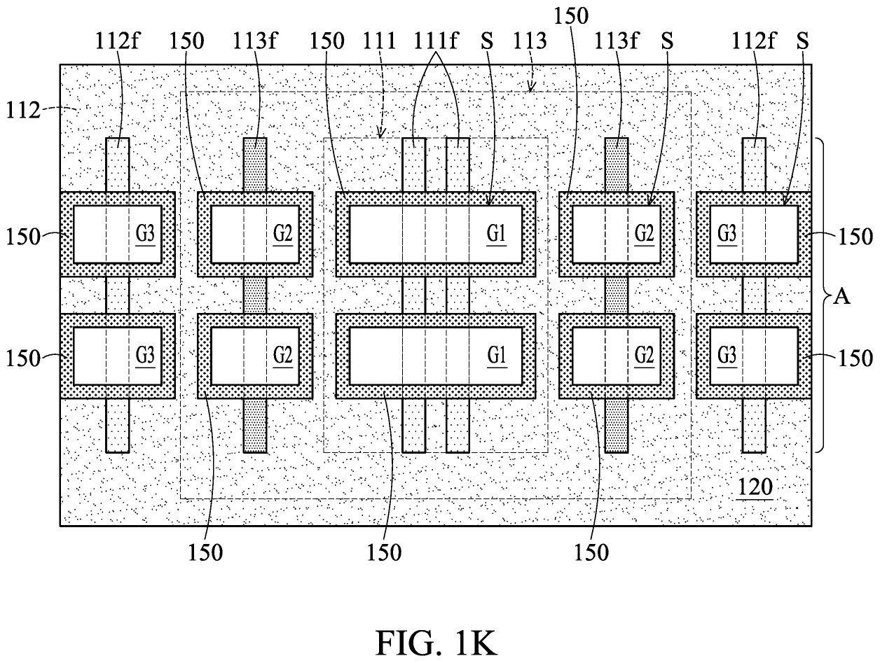

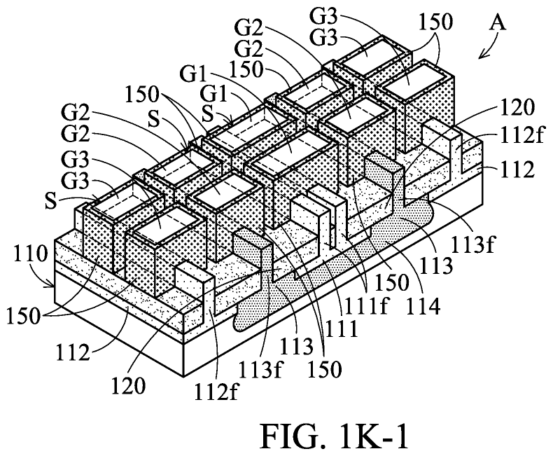

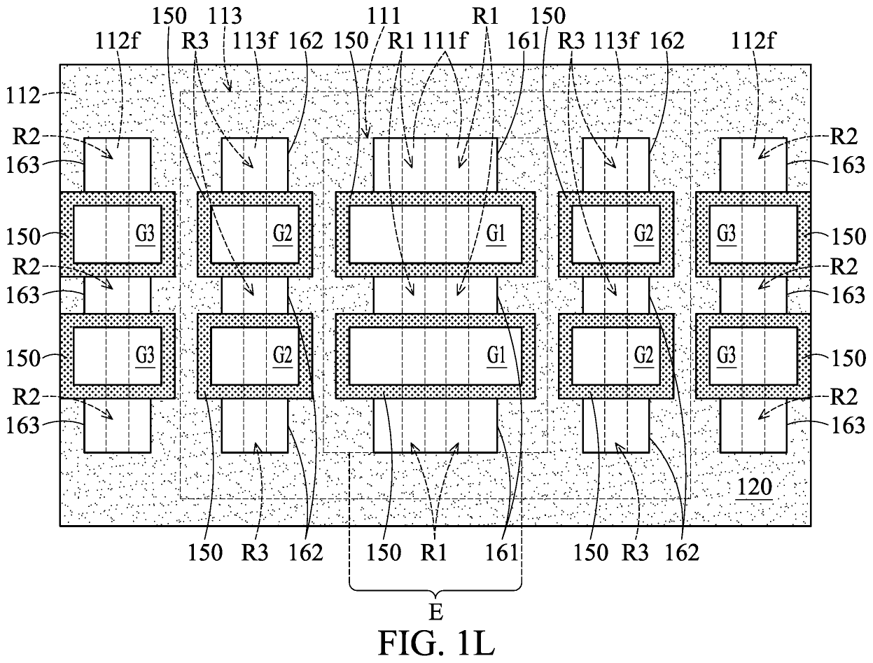

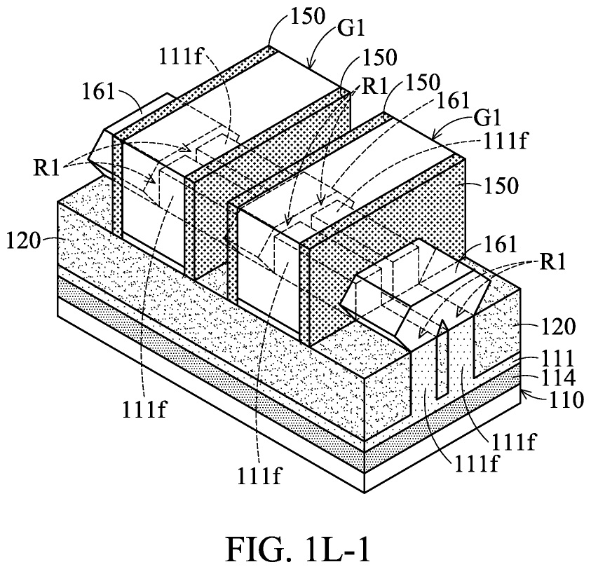

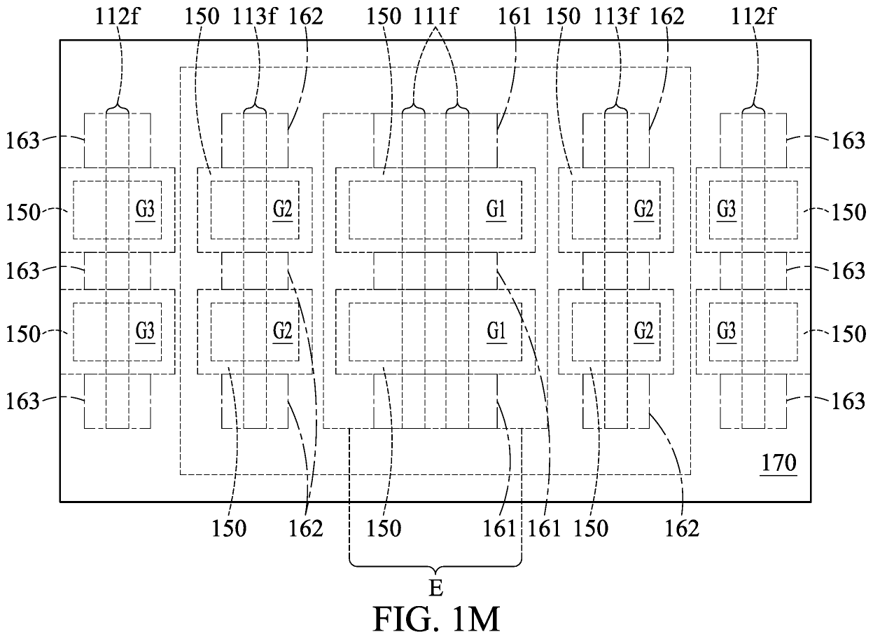

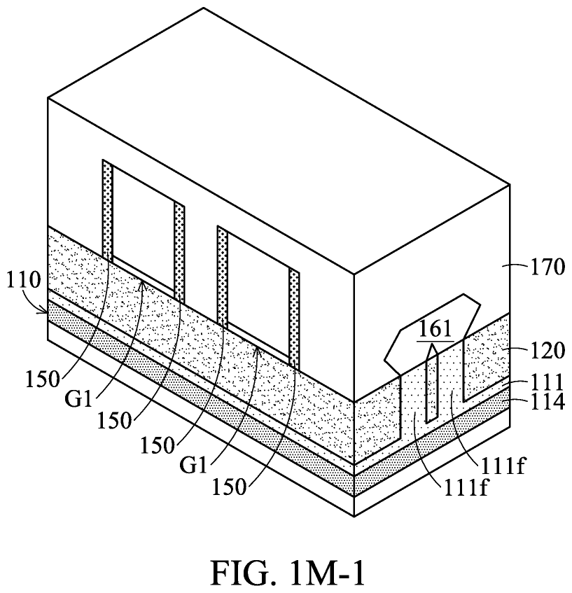

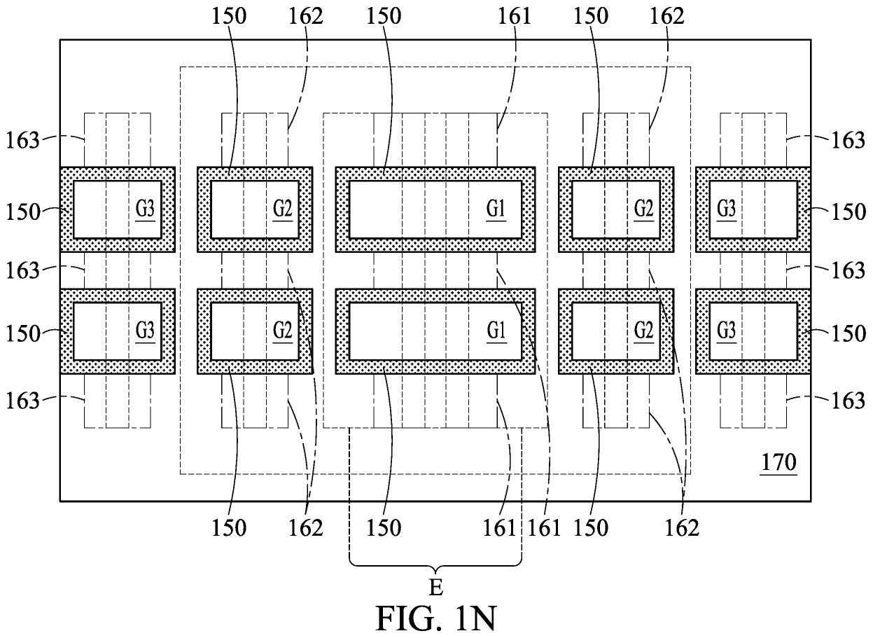

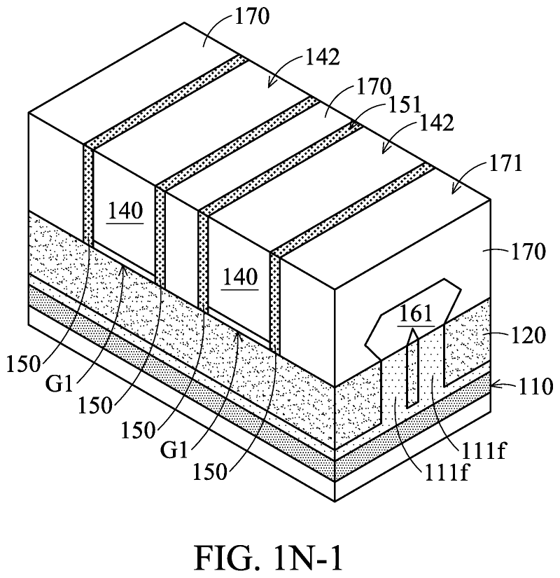

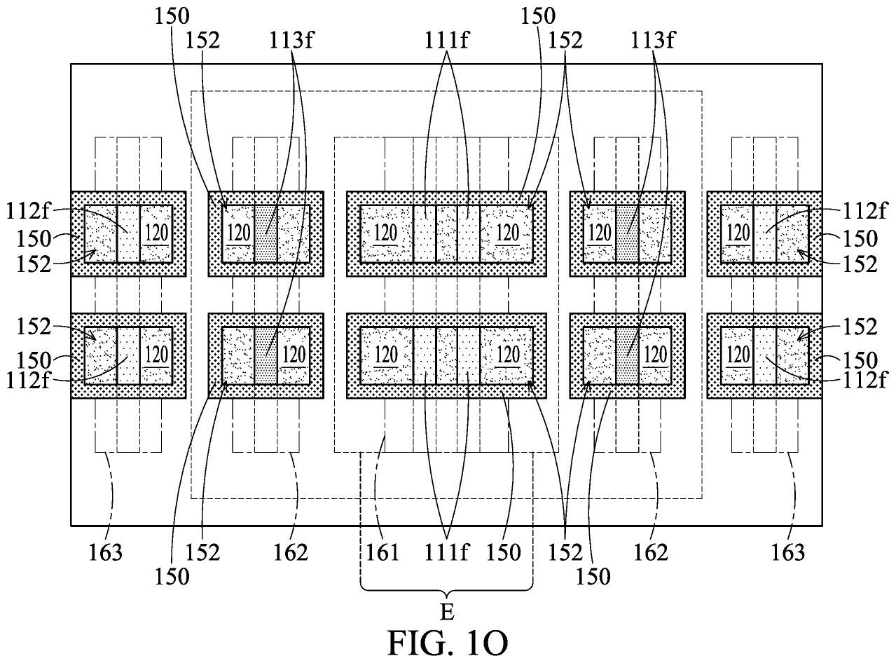

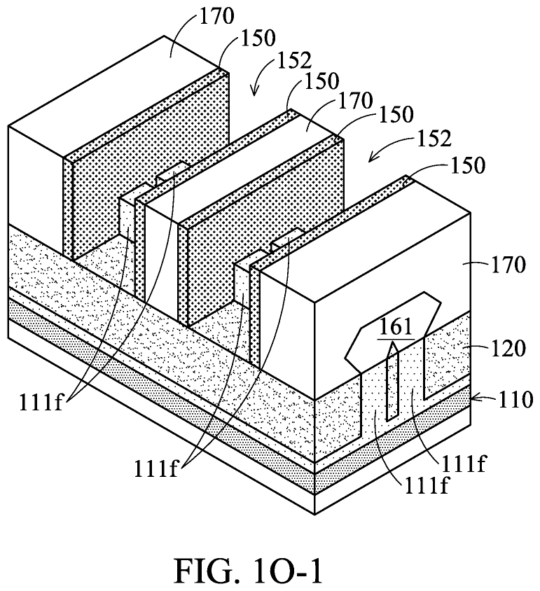

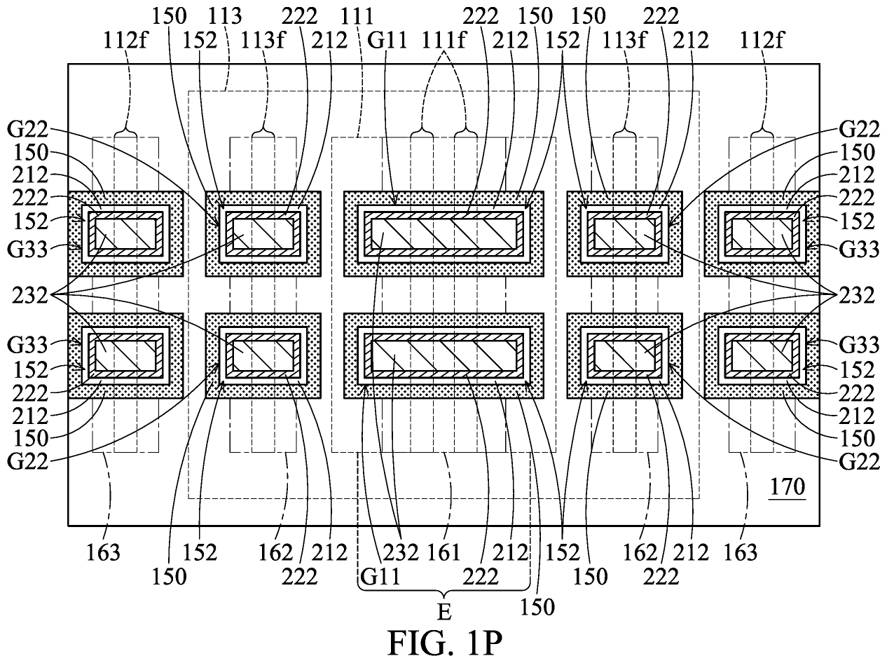

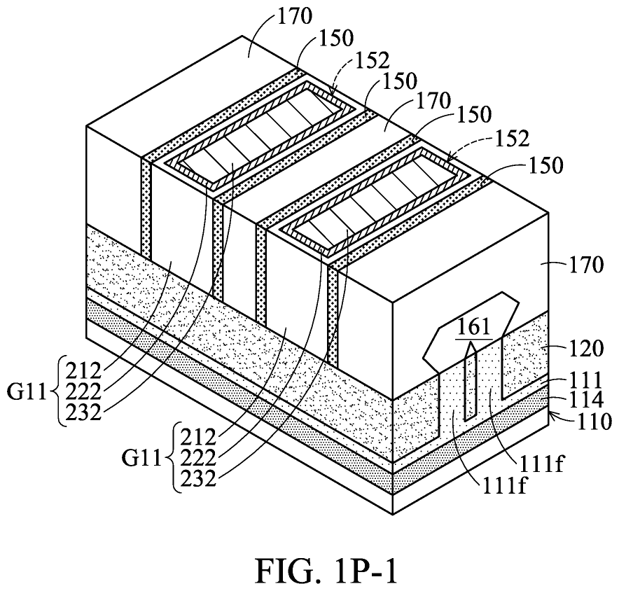

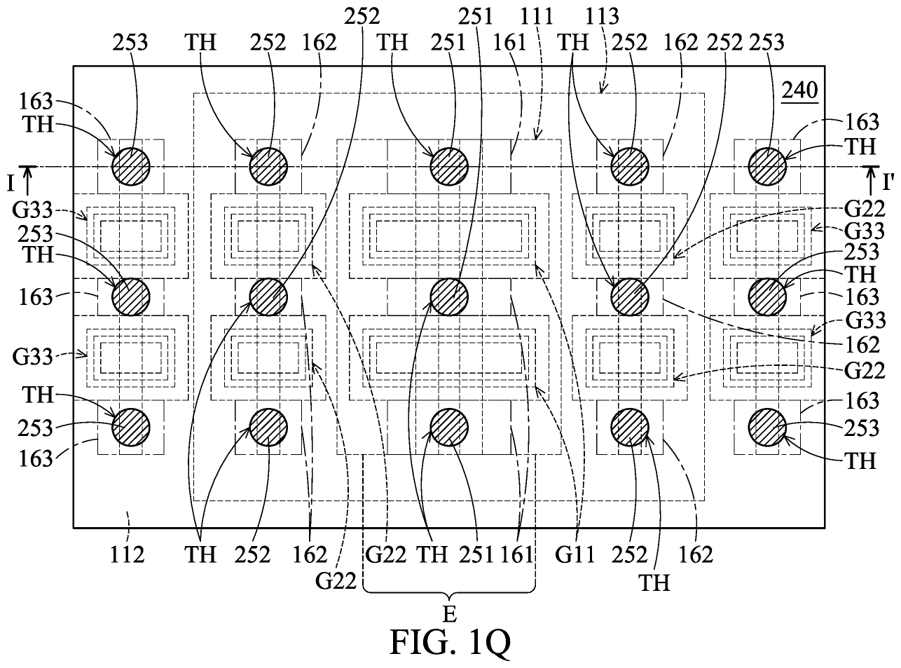

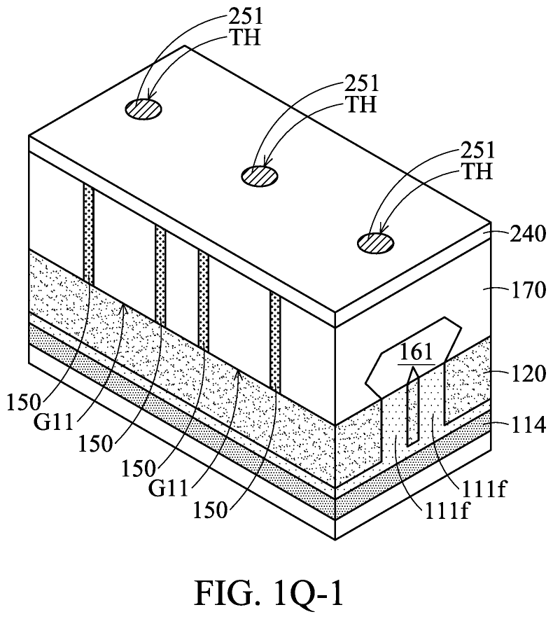

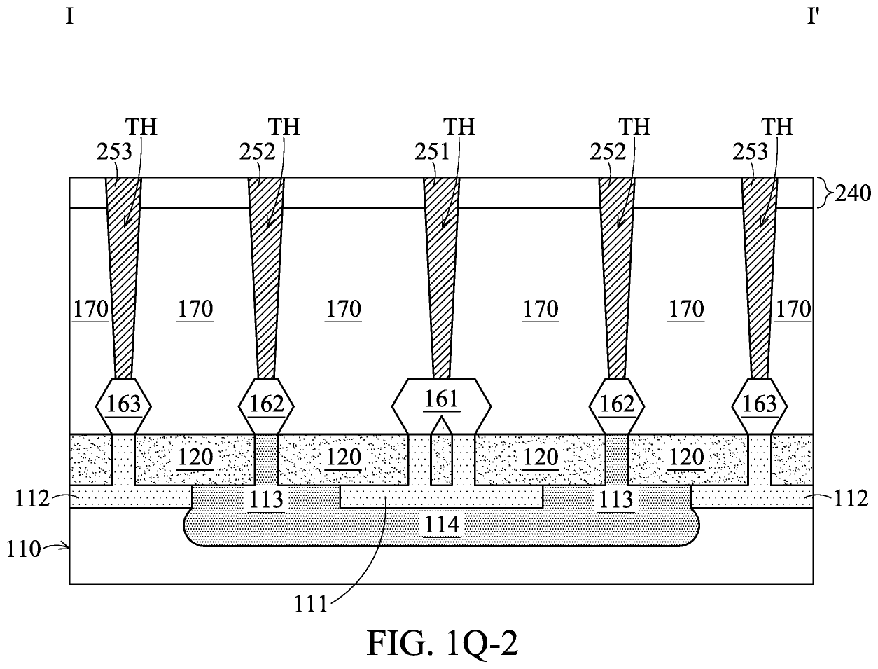

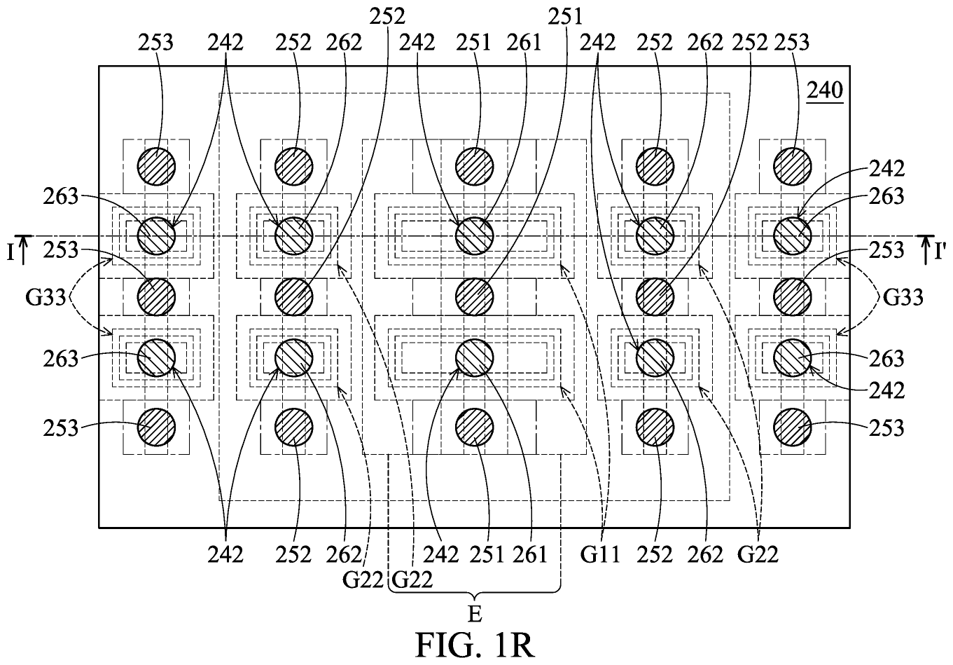

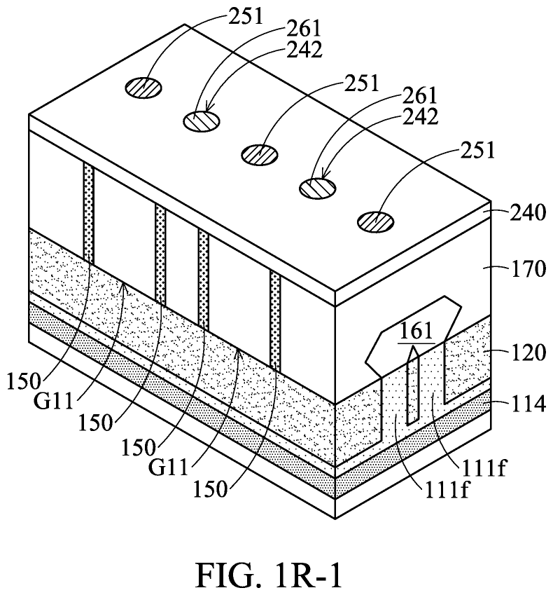

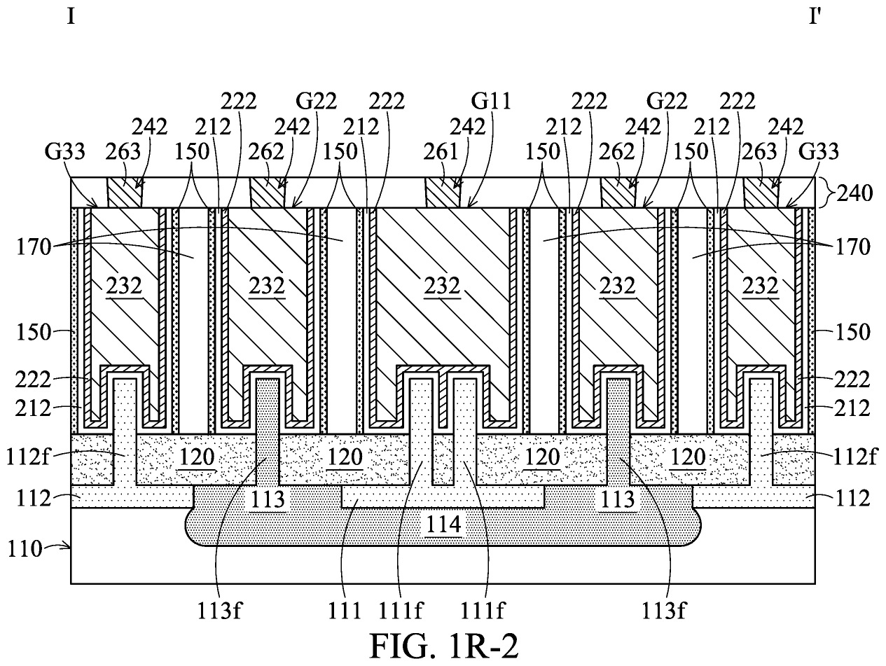

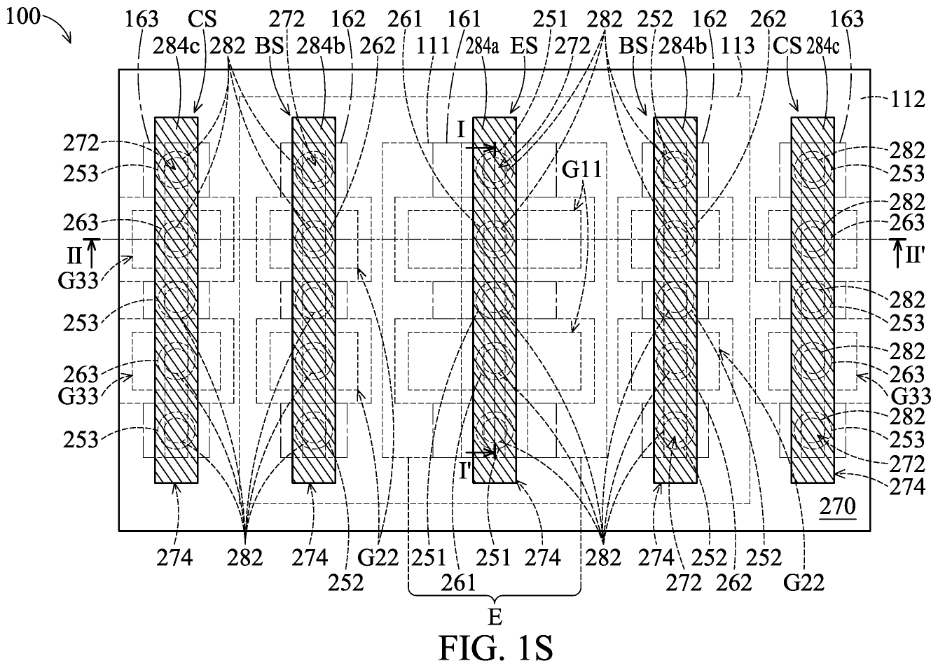

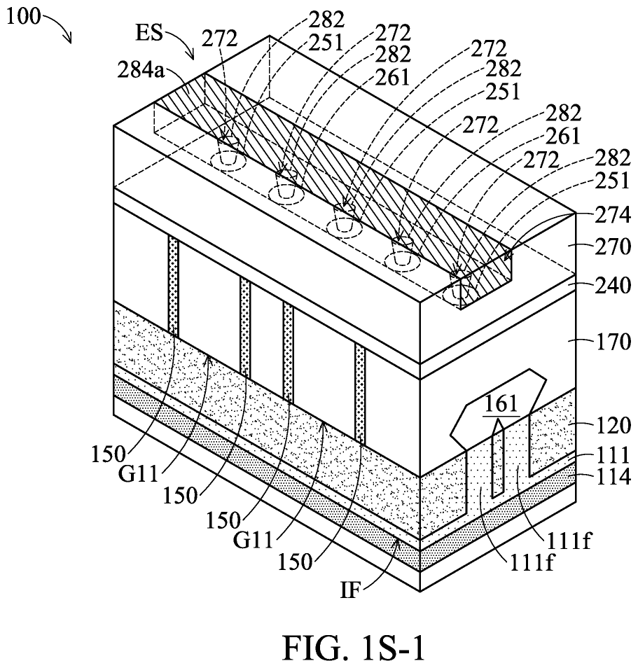

FIGS. 1A-1S are top views of various stages of a process for forming a semiconductor device structure, in accordance with some embodiments. FIG. 1A-1 is a perspective view of the semiconductor device structure of FIG. 1A, in accordance with some embodiments.

As shown in FIGS. 1A and 1A-1, a substrate 110 is provided, in accordance with some embodiments. The substrate 110 includes, for example, a semiconductor substrate. The substrate 110 includes, for example, a semiconductor wafer (such as a silicon wafer) or a portion of a semiconductor wafer.

In some embodiments, the substrate 110 is made of an elementary semiconductor material including silicon or germanium in a single crystal structure, a polycrystal structure, or an amorphous structure. In some other embodiments, the substrate 110 is made of a compound semiconductor, such as silicon carbide, gallium arsenide, gallium phosphide, indium phosphide, indium arsenide, an alloy semiconductor, such as SiGe or GaAsP, or a combination thereof. The substrate 110 may also include multi-layer semiconductors, semiconductor on insulator (SOI) (such as silicon on insulator or germanium on insulator), or a combination thereof. In some embodiments, the substrate 110 is a P-type substrate.

In some embodiments, the substrate 110 is a device wafer that includes various device elements. In some embodiments, the various device elements are formed in and/or over the substrate 110. The device elements are not shown in figures for the purpose of simplicity and clarity. Examples of the various device elements include active devices, passive devices, other suitable elements, or a combination thereof. The active devices may include transistors or diodes (not shown) formed at a surface of the substrate 110. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc. Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate 110. The isolation features are used to surround active regions and electrically isolate various device elements formed in and/or over the substrate 110 in the active regions. In some embodiments, the isolation features include shallow trench isolation (STI) features, local oxidation of silicon (LOCOS) features, other suitable isolation features, or a combination thereof.

FIGS. 1B-1 to 1H-1 are cross-sectional views illustrating the semiconductor device structure along a sectional line I-I′ in FIGS. 1B-1H, in accordance with some embodiments. As shown in FIGS. 1B and 1B-1, a mask layer M1 is formed over the substrate 110, in accordance with some embodiments. The mask layer M1 has openings OP1 and OP2, in accordance with some embodiments. The openings OP1 and OP2 expose portions of the substrate 110, in accordance with some embodiments. The mask layer M1 is made of a polymer material such as a photoresist material, in accordance with some embodiments.

As shown in FIGS. 1B and 1B-1, an implantation process is performed over the substrate 110 to form well regions 111 and 112 in the portions of the substrate 110 exposed by the openings OP1 and OP2, in accordance with some embodiments. The well regions 111 and 112 are P-type well regions, in accordance with some embodiments. The well regions 111 and 112 are doped with P-type dopants, in accordance with some embodiments.

The P-type dopants include the Group IIIA element, in accordance with some embodiments. The Group IIIA element includes boron or another suitable material. In some embodiments, a concentration of the P-type dopants in the well regions 111 and 112 ranges from about 1E12 atoms/cm³ to about 1E14 atoms/cm³.

As shown in FIGS. 1C and 1C-1, the mask layer M1 is removed, in accordance with some embodiments. As shown in FIGS. 1C and 1C-1, a mask layer M2 is formed over the well regions 111 and 112 of the substrate 110, in accordance with some embodiments. The mask layer M2 has an opening OP3, in accordance with some embodiments. The opening OP3 exposes a portion of the substrate 110, in accordance with some embodiments. The mask layer M2 is made of a polymer material such as a photoresist material, in accordance with some embodiments.

As shown in FIGS. 1C and 1C-1, an implantation process is performed over the substrate 110 to form a well region 113 in the portion of the substrate 110 exposed by the opening OP3, in accordance with some embodiments. The well region 113 is between the well regions 111 and 112, in accordance with some embodiments.

The well region 113 separates the well region 111 from the well region 112, in accordance with some embodiments. The well region 113 surrounds the well region 111, in accordance with some embodiments. The well region 112 surrounds the well regions 111 and 113, in accordance with some embodiments. The well region 113 is an N-type well region, in accordance with some embodiments.

The well region 113 is doped with N-type dopants, in accordance with some embodiments. The N-type dopants include the Group VA element, in accordance with some embodiments. The Group VA element includes phosphor (P), antimony (Sb), or another suitable Group VA material. In some embodiments, a concentration of the N-type dopants in the well region 113 ranges from about 1E12 atoms/cm³ to about 1E14 atoms/cm³.

As shown in FIGS. 1D and 1D-1, the mask layer M2 is removed, in accordance with some embodiments. As shown in FIGS. 1D and 1D-1, a mask layer M3 is formed over the well region 112 of the substrate 110, in accordance with some embodiments. The mask layer M3 has an opening OP4, in accordance with some embodiments. The opening OP4 exposes the well regions 111 and 113 of the substrate 110, in accordance with some embodiments.

The mask layer M3 has a left portion M3L, a right portion M3R, a front portion M3F, and a rear portion M3A, in accordance with some embodiments. The mask layer M3 is made of a polymer material such as a photoresist material, in accordance with some embodiments.

As shown in FIGS. 1D and 1D-1, an implantation process is performed over the well regions 111 and 113 of the substrate 110 to form a deep well region 114 in the substrate 110 under the well regions 111 and 113, in accordance with some embodiments. The well region 113 and the deep well region 114 separate the well region 111 from the well region 112, in accordance with some embodiments.

In some embodiments, the substrate 110 is a (100) substrate such as a Si (100) substrate (e.g., a P-type Si (100) substrate). In some embodiments, an included angle θ1 between an implantation direction 210 of the implantation process and a top surface 116 of the substrate 110 ranges from greater than about 90° to about 120°, which is able to eliminate the implant channeling effect in the substrate 110.

However, since a portion of the substrate 110 under the well regions 111 and 113 is shadowed by the left portion M3L of the mask layer M3, the deep well region 114 has an asymmetric shape, in accordance with some embodiments. The deep well region 114 has opposite sidewalls 114a and 114b, in accordance with some embodiments. The sidewall 114a is a sloped surface, in accordance with some embodiments. The sidewall 114b is a convex curved surface, in accordance with some embodiments.

The well region 114 is an N-type well region, in accordance with some embodiments. The well region 114 is doped with N-type dopants, in accordance with some embodiments. The N-type dopants include the Group VA element, in accordance with some embodiments. The Group VA element includes phosphor (P), antimony (Sb), or another suitable Group VA material.

In some embodiments, a concentration of the N-type dopants in the well region 114 ranges from about 1E12 atoms/cm³ to about 1E14 atoms/cm³. In some embodiments, a portion of the substrate 110, which is outside of the well regions 111 and 112, the well region 113, and the deep well region 114, has the P-type of conductivity.

As shown in FIGS. 1E and 1E-1, an implantation process is performed over the well regions 111 and 113 of the substrate 110 to widen the deep well region 114 in the substrate 110, in accordance with some embodiments. In some embodiments, an included angle θ2 between an implantation direction 211 of the implantation process and the top surface 116 of the substrate 110 ranges from about 60° to less than about 90°, which is able to eliminate the implant channeling effect in the substrate 110.

The implantation direction 210 of the implantation process of FIG. 1D-1 is different from the implantation direction 211 of the implantation process of FIG. 1E-1, in accordance with some embodiments. After the implantation process, the sidewall 114a of the deep well region 114 becomes a convex curved surface, in accordance with some embodiments. As shown in FIG. 1E-1, the deep well region 114 has a symmetric shape such as a strip shape, in accordance with some embodiments.

As shown in FIGS. 1F and 1F-1, an implantation process is performed over the well regions 111 and 113 of the substrate 110 to widen the deep well region 114 in the substrate 110, in accordance with some embodiments. In some embodiments, an included angle θ3 between an implantation direction 213 of the implantation process and the top surface 116 of the substrate 110 ranges from greater than about 90° to about 120°, which is able to eliminate the implant channeling effect in the substrate 110.

However, since a portion of the substrate 110 under the well regions 111 and 113 is shadowed by the front portion M3F of the mask layer M3, the deep well region 114 has an asymmetric shape, in accordance with some embodiments. The deep well region 114 has opposite sidewalls 114c and 114d, in accordance with some embodiments. The sidewall 114c is a sloped surface, in accordance with some embodiments. The sidewall 114d is a convex curved surface, in accordance with some embodiments.

As shown in FIGS. 1G and 1G-1, an implantation process is performed over the well regions 111 and 113 of the substrate 110 to widen the deep well region 114 in the substrate 110, in accordance with some embodiments. In some embodiments, an included angle θ4 between an implantation direction 214 of the implantation process and the top surface 116 of the substrate 110 ranges from about 60° to less than about 90°, which is able to eliminate the implant channeling effect in the substrate 110.

The implantation direction 213 of the implantation process of FIG. 1F-1 is different from the implantation direction 214 of the implantation process of FIG. 1G-1, in accordance with some embodiments. After the implantation process, the sidewall 114c of the deep well region 114 becomes a convex curved surface, in accordance with some embodiments. As shown in FIG. 1G-1, the deep well region 114 has a symmetric shape such as a strip shape, in accordance with some embodiments.

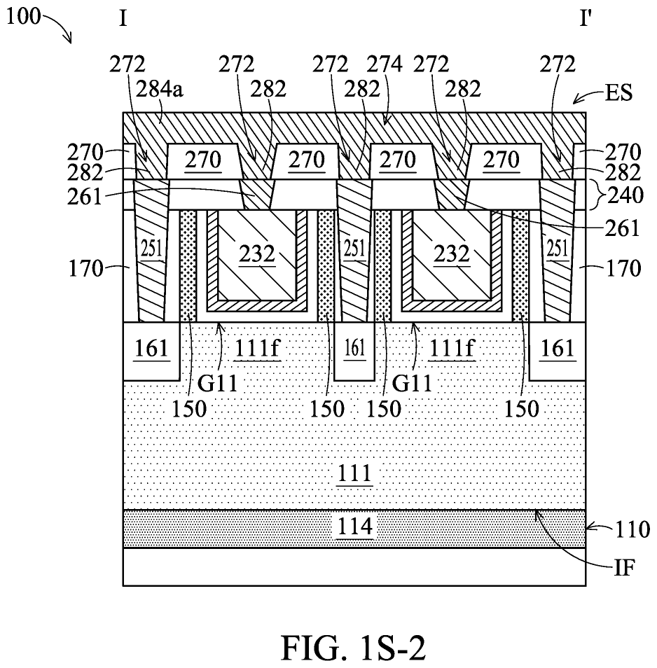

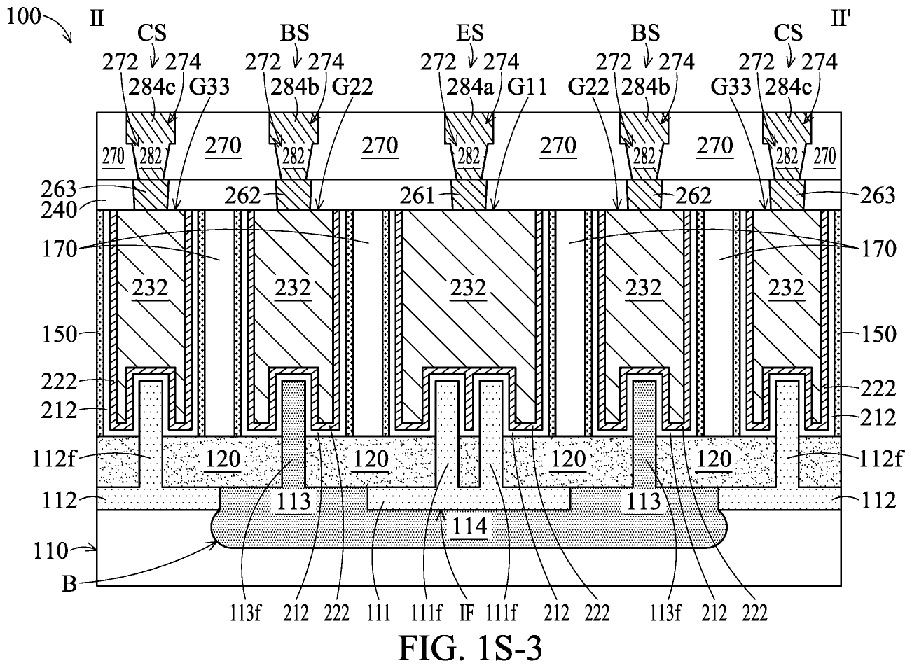

FIG. 1H-2 is a cross-sectional view illustrating the semiconductor device structure along a sectional line II-IF in FIG. 1H, in accordance with some embodiments. FIG. 1H-3 is a perspective view of the semiconductor device structure of FIG. 1H, in accordance with some embodiments. FIG. 1H-4 is a perspective view of a portion A of the semiconductor device structure of FIG. 1H-3, in accordance with some embodiments.

As shown in FIGS. 1H, 1H-1, 1H-2, 1H-3 and 1H-4, the mask layer M3 is removed, in accordance with some embodiments. As shown in FIGS. 1H, 1H-1, 1H-2, 1H-3 and 1H-4, the well region 113 and the deep well region 114 together form a base well region B, in accordance with some embodiments. As shown in FIG. 1H-1, the base well region B has a first U-like shape, in accordance with some embodiments. As shown in FIG. 1H-2, the base well region B has a second U-like shape, in accordance with some embodiments.

FIGS. 1I-1 to 1K-1 are perspective views of a portion A of the semiconductor device structure in FIGS. 1I-1K, in accordance with some embodiments. As shown in FIGS. 1I and 1I-1, the substrate 110 is partially removed to form recesses R110 in the substrate 110, in accordance with some embodiments.

After the removal process, the substrate 110 has fins 111f, 112f, and 113f and a base 115, in accordance with some embodiments. The fins 111f, 112f, and 113f are formed over the base 115, in accordance with some embodiments. The fins 111f, 112f, and 113f are formed in the well regions 111, 112, and 113 respectively, in accordance with some embodiments. The fins 111f, 112f and 113f are spaced apart from each other, in accordance with some embodiments. The fins 111f, 112f, and 113f are between the recesses R110, in accordance with some embodiments.

As shown in FIGS. 1J and 1J-1, an isolation layer 120 is formed over the base 115, in accordance with some embodiments. Each fin 111f, 112f or 113f is partially in the isolation layer 120, in accordance with some embodiments. The isolation layer 120 includes oxide (such as silicon oxide), in accordance with some embodiments. The isolation layer 120 is formed by a chemical vapor deposition (CVD) process and an etching back process, in accordance with some embodiments.

As shown in FIGS. 1J and 1J-1, gate stacks G are formed over and across the fins 111f, 112f and 113f, in accordance with some embodiments. Each gate stack G has a gate dielectric layer 130 and a gate electrode 140 over the gate dielectric layer 130, in accordance with some embodiments.

The gate dielectric layer 130 is positioned between the gate electrode 140 and the fins 111f, 112f and 113f, in accordance with some embodiments. The gate dielectric layer 130 is also positioned between the gate electrode 140 and the isolation layer 120, in accordance with some embodiments.

The gate dielectric layer 130 is made of oxides such as silicon oxide, in accordance with some embodiments. The gate dielectric layer 130 is formed using a chemical vapor deposition process (CVD process) and an etching process, in accordance with some embodiments.

The gate electrode 140 is made of a semiconductor material such as polysilicon, in accordance with some embodiments. The gate electrode 140 is formed using a chemical vapor deposition process and an etching process, in accordance with some embodiments.

As shown in FIGS. 1K and 1K-1, the gate stacks G are partially removed to divide each gate stack G into gate stacks G1, G2 and G3, in accordance with some embodiments. Each gate stack G1 is over and wrapped around upper portions of the fins 111f, in accordance with some embodiments. Each gate stack G2 is over and wrapped around an upper portion of the corresponding fin 113f, in accordance with some embodiments. Each gate stack G3 is over and wrapped around an upper portion of the corresponding fin 112f, in accordance with some embodiments.

As shown in FIGS. 1K and 1K-1, a spacer layer 150 is formed over sidewalls S of the gate stacks G1, G2 and G3, in accordance with some embodiments. The spacer layer 150 surrounds the gate stacks G1, G2 and G3, in accordance with some embodiments. The spacer layer 150 is positioned over the fins 111f, 112f and 113f and the isolation layer 120, in accordance with some embodiments.

The spacer layer 150 includes insulating materials, such as silicon oxide, silicon nitride, silicon oxynitride, or silicon carbide, in accordance with some embodiments. The formation of the spacer layer 150 includes a deposition process and an anisotropic etching process, in accordance with some embodiments. The anisotropic etching process includes a dry etching process, in accordance with some embodiments.

FIGS. 1L-1 to 1S-1 are perspective views of a portion E of the semiconductor device structure in FIGS. 1L-1S, in accordance with some embodiments. As shown in FIGS. 1L and 1L-1, portions of the fins 111f, 112f and 113f, which are outside of the isolation layer 120 and not covered by the gate stacks G1, G2 and G3 and the spacer layer 150, are removed to form recesses R1, R2, and R3 in the fins 111f, 112f, and 113f respectively, in accordance with some embodiments. The removal process includes an etching process, in accordance with some embodiments.

As shown in FIGS. 1L and 1L-1, epitaxial structures 161, 162 and 163 are formed in the recesses R1, R3, and R2 respectively, in accordance with some embodiments. The epitaxial structures 161, 162, and 163 are partially embedded in the fins 111f, 113f, and 112f respectively, in accordance with some embodiments. The epitaxial structures 161, 162 and 163 are in direct contact with the fins 111f, 113f and 112f respectively, in accordance with some embodiments.

The epitaxial structures 161 are positioned on two opposite sides of each gate stack G1, in accordance with some embodiments. The epitaxial structures 162 are positioned on two opposite sides of each gate stack G2, in accordance with some embodiments. The epitaxial structures 163 are positioned on two opposite sides of each gate stack G3, in accordance with some embodiments.

The well regions 111 and 112 and the epitaxial structures 161 and 163 have a P-type of conductivity, in accordance with some embodiments. The deep well region 114, the well region 113, and the epitaxial structures 162 have an N-type of conductivity, in accordance with some embodiments.

In some embodiments, the epitaxial structures 161 and 163 are made of a P-type conductivity material, in accordance with some embodiments. The P-type conductivity material includes silicon germanium (SiGe) or another suitable P-type conductivity material.

The epitaxial structures 161 and 163 are doped with the Group IIIA element, in accordance with some embodiments. The Group IIIA element includes boron or another suitable material. The epitaxial structures 161 and 163 are formed using a first epitaxial process, in accordance with some embodiments.

The epitaxial structures 162 are made of an N-type conductivity material, in accordance with some embodiments. The N-type conductivity material includes silicon phosphorus (SiP) or another suitable N-type conductivity material. The epitaxial structures 162 are doped with the Group VA element, in accordance with some embodiments. The Group VA element includes phosphor (P), antimony (Sb), or another suitable Group VA material.

The epitaxial structures 161, 162 and 163 are also referred to as doped structures, in accordance with some embodiments. The epitaxial structures 162 are formed using a second epitaxial process, in accordance with some embodiments. The first epitaxial process and the second epitaxial process are performed individually, in accordance with some embodiments.

As shown in FIGS. 1M and 1M-1, a dielectric layer 170 is formed over the gate stacks G1, G2 and G3, the spacer layer 150, the isolation layer 120, and the epitaxial structures 161, 162 and 163, in accordance with some embodiments. The dielectric layer 170 is made of a dielectric material such as silicon oxide, silicon oxynitride, borosilicate glass (BSG), phosphoric silicate glass (PSG), borophosphosilicate glass (BPSG), fluorinated silicate glass (FSG), a low-k material, a porous dielectric material, or a combination thereof, in accordance with some embodiments. The dielectric layer 170 is formed by a chemical vapor deposition (CVD) process, in accordance with some embodiments.

As shown in FIGS. 1N and 1N-1, a planarization process is then performed on the dielectric layer 170 until top surfaces 142 of the gate electrodes 140 are exposed, in accordance with some embodiments. The planarization process includes a chemical mechanical polishing (CMP) process, in accordance with some embodiments.

As shown in FIGS. 1O and 1O-1, the gate stacks G1, G2 and G3 are removed, in accordance with some embodiments. The removal process includes a wet etching process, in accordance with some embodiments. After the removal process, trenches 152 are formed in the spacer layer 150, in accordance with some embodiments. The trenches 152 expose portions of the fins 111f, 112f and 113f, in accordance with some embodiments.

As shown in FIGS. 1P and 1P-1, a gate dielectric layer 212 is formed in the trenches 152 to cover the fins 111f, 112f and 113f exposed by the trenches 152, in accordance with some embodiments. The gate dielectric layer 212 is made of a dielectric material such as silicon oxide, silicon nitride, silicon oxynitride, a high dielectric constant (high-K) material, or a combination thereof.

Examples of high-K dielectric materials include hafnium oxide, zirconium oxide, aluminum oxide, hafnium dioxide-alumina alloy, hafnium silicon oxide, hafnium silicon oxynitride, hafnium tantalum oxide, hafnium titanium oxide, hafnium zirconium oxide, another suitable high-K material, or a combination thereof.

Thereafter, as shown in FIGS. 1P and 1P-1, a work function metal layer 222 is deposited over the gate dielectric layer 212, in accordance with some embodiments. In the embodiments, the work function metal layers 222 can be a p-type metal capable of providing a work function value suitable for the device, such as equal to or greater than about 4.8 eV. The p-type metal may be made of metal, metal carbide, metal nitride, other suitable materials, or a combination thereof. For example, the p-type metal is made of titanium, titanium nitride, other suitable materials, or a combination thereof.

In the embodiments, the work function metal layer 222 can be an n-type metal capable of providing a work function value suitable for the device, such as equal to or less than about 4.5 eV. The n-type metal may be made of metal, metal carbide, metal nitride, or a combination thereof. For example, the n-type metal is made of tantalum, tantalum nitride, or a combination thereof.

Afterwards, as shown in FIGS. 1P and 1P-1, gate electrodes 232 (also called metal gate electrodes) are formed over the work function metal layer 222 to fill the trenches 152, in accordance with some embodiments. The gate electrodes 232 are made of a suitable metal material, such as aluminum, tungsten, gold, platinum, cobalt, another suitable metal, an alloy thereof, or a combination thereof, in accordance with some embodiments.

The gate electrode 232, the work function metal layer 222, and the gate dielectric layer 212 in the same trench 152 over the fin 111f together form a gate stack G11, in accordance with some embodiments. The gate electrode 232, the work function metal layer 222, and the gate dielectric layer 212 in the same trench 152 over the fin 113f together form a gate stack G22, in accordance with some embodiments. The gate electrode 232, the work function metal layer 222, and the gate dielectric layer 212 in the same trench 152 over the fin 112f together form a gate stack G33, in accordance with some embodiments.

FIG. 1Q-2 is a cross-sectional view illustrating the semiconductor device structure along a sectional line I-I′ in FIG. 1Q, in accordance with some embodiments. As shown in FIGS. 1Q, 1Q-1 and 1Q-2, a dielectric layer 240 is formed over the dielectric layer 170, the spacer layer 150 and the gate stacks G11, G22 and G33, in accordance with some embodiments.

The dielectric layer 240 is made of a dielectric material such as silicon oxide, silicon oxynitride, borosilicate glass (BSG), phosphoric silicate glass (PSG), borophosphosilicate glass (BPSG), fluorinated silicate glass (FSG), a low-k material, a porous dielectric material, or a combination thereof, in accordance with some embodiments.

As shown in FIGS. 1Q, 1Q-1 and 1Q-2, portions of the dielectric layer 240 and the dielectric layer 170 are removed to form through holes TH passing through the dielectric layer 240 and the dielectric layer 170, in accordance with some embodiments. The through holes TH expose portions of the epitaxial structures 161, 162 and 163, in accordance with some embodiments. The portions of the dielectric layer 240 and the dielectric layer 170 are removed using a photolithography process and an etching process such as a dry etching process, in accordance with some embodiments.

As shown in FIGS. 1Q, 1Q-1 and 1Q-2, contact plugs 251, 252 and 253 are formed in the through holes TH to be connected to the epitaxial structures 161, 162 and 163 exposed by the through holes TH, in accordance with some embodiments.

The contact plugs 251, 252 and 253 is made of tungsten (W), aluminum (Al), gold (Au), silver (Ag), a combination thereof, an alloy thereof, or another suitable conductive material, in accordance with some embodiments. The contact plugs 251, 252 and 253 are formed using a deposition process and a planarization process, in accordance with some embodiments. The deposition process includes a physical vapor deposition (PVD) process, in accordance with some embodiments. The planarization process includes a chemical mechanical polishing (CMP) process, in accordance with some embodiments.

FIG. 1R-2 is a cross-sectional view illustrating the semiconductor device structure along a sectional line I-I′ in FIG. 1R, in accordance with some embodiments. As shown in FIGS. 1R, 1R-1 and 1R-2, portions of the dielectric layer 240 are removed to form through holes 242 passing through the dielectric layer 240, in accordance with some embodiments.

The through holes 242 expose portions of the gate stacks G11, G22 and G33, in accordance with some embodiments. The portions of the dielectric layer 240 are removed using a photolithography process and an etching process such as a dry etching process, in accordance with some embodiments.

As shown in FIGS. 1R, 1R-1 and 1R-2, contact structures 261, 262 and 263 are formed in the through holes 242 to be connected to the gate stacks G11, G22 and G33 respectively, in accordance with some embodiments. The contact structures 261, 262 and 263 is made of tungsten (W), aluminum (Al), gold (Au), silver (Ag), a combination thereof, an alloy thereof, or another suitable conductive material, in accordance with some embodiments.

The contact structures 261, 262 and 263 are formed using a deposition process and a planarization process, in accordance with some embodiments. The deposition process includes a physical vapor deposition (PVD) process, in accordance with some embodiments. The planarization process includes a chemical mechanical polishing (CMP) process, in accordance with some embodiments.

FIG. 1S-2 is a cross-sectional view illustrating the semiconductor device structure along a sectional line I-I′ in FIG. 1S, in accordance with some embodiments. FIG. 1S-3 is a cross-sectional view illustrating the semiconductor device structure along a sectional line II-IF in FIG. 15, in accordance with some embodiments.

As shown in FIGS. 15 and 1S-1, a dielectric layer 270 is formed over the dielectric layer 240, the contact plugs 251, 252 and 253 and the contact structures 261, 262 and 263, in accordance with some embodiments. The dielectric layer 270 is made of a dielectric material such as silicon oxide, silicon oxynitride, borosilicate glass (BSG), phosphoric silicate glass (PSG), borophosphosilicate glass (BPSG), fluorinated silicate glass (FSG), a low-k material, a porous dielectric material, or a combination thereof, in accordance with some embodiments.

As shown in FIGS. 1S, 1S-1, 1S-2 and 1S-3, portions of the dielectric layer 270 are removed to form through holes 272 and trenches 274 in the dielectric layer 270, in accordance with some embodiments. The through holes 272 are under the corresponding trench 274, in accordance with some embodiments. The through holes 272 are arranged along the corresponding trench 274, in accordance with some embodiments. The through holes 272 are connected to the trench 274 thereover, in accordance with some embodiments.

The trench 274 extends across the corresponding through holes 272, in accordance with some embodiments. The through holes 272 and the trenches 274 expose the contact structures 261, 262 and 263 and the contact plugs 251, 252 and 253, in accordance with some embodiments. The removal process includes an etching process such as a dual damascene process, in accordance with some embodiments.

As shown in FIGS. 1S, 1S-1, 1S-2 and 1S-3, conductive via structures 282 are formed in the through holes 272, and conductive lines 284a, 284b, and 284c are formed in the trenches 274, in accordance with some embodiments. The conductive via structures 282 are connected to the contact structures 261, 262 and 263 thereunder and the contact plugs 251, 252 and 253 thereunder, in accordance with some embodiments.

As shown in FIGS. 1S, 1S-1 and 1S-2, the conductive line 284a is electrically connected to the contact structures 261 thereunder and the contact plugs 251 thereunder through the conductive via structures 282 thereunder, in accordance with some embodiments. The conductive line 284a is over and extends across the gate stacks G11 and the epitaxial structures 161, in accordance with some embodiments. The conductive line 284a is electrically connected to the gate stacks G11 and the epitaxial structures 161 through the conductive via structures 282, the contact structures 261, and the contact plugs 251, in accordance with some embodiments.

As shown in FIGS. 1S and 1S-3, each conductive line 284b is electrically connected to the contact structures 262 thereunder and the contact plugs 252 thereunder through the conductive via structures 282 thereunder, in accordance with some embodiments. The conductive line 284b is over and extends across the corresponding gate stacks G22 and the corresponding epitaxial structures 162, in accordance with some embodiments.

The conductive line 284b is electrically connected to the corresponding gate stacks G22 and the corresponding epitaxial structures 162 through the corresponding conductive via structures 282, the corresponding contact structures 262, and the corresponding contact plugs 252, in accordance with some embodiments. The conductive lines 284b are grounded, in accordance with some embodiments.

As shown in FIGS. 1S and 1S-3, each conductive line 284c is electrically connected to the contact structures 263 thereunder and the contact plugs 253 thereunder through the conductive via structures 282 thereunder, in accordance with some embodiments. The conductive line 284c is over and extends across the corresponding gate stacks G33 and the corresponding epitaxial structures 163, in accordance with some embodiments.

The conductive line 284c is electrically connected to the corresponding gate stacks G33 and the corresponding epitaxial structures 163 through the corresponding conductive via structures 282, the corresponding contact structures 263, and the corresponding contact plugs 253, in accordance with some embodiments. The conductive lines 284c are grounded, in accordance with some embodiments. As shown in FIG. 1S-3, the gate stacks G11, G22 and G33 are wrapped around upper portions of the fins 111f, 113f and 112f respectively, in accordance with some embodiments.

In this step, a semiconductor device structure 100 is substantially formed, in accordance with some embodiments. The semiconductor device structure 100 includes a bipolar junction transistor (BJT), in accordance with some embodiments. In some embodiments, the semiconductor device structure 100 is a PNP type BJT. The conductive line 284a, the conductive via structures 282 thereunder, the contact structures 261, the contact plugs 251, the gate stacks G11, the epitaxial structures 161, the fins 111f, and the well region 111 together form an emitter structure ES, in accordance with some embodiments. The well region 111 is also referred to as an emitter well region, in accordance with some embodiments.

The conductive line 284b, the conductive via structures 282 thereunder, the contact structures 262, the contact plugs 252, the gate stacks G22, the epitaxial structures 162, the fins 113f, and the base well region B (i.e., the well region 113 and the deep well region 114) together form a base structure BS, in accordance with some embodiments.

The conductive line 284c, the conductive via structures 282 thereunder, the contact structures 263, the contact plugs 253, the gate stacks G33, the epitaxial structures 163, the fins 112f, and the well region 112 together form a collector structure CS, in accordance with some embodiments. The well region 112 is also referred to as a collector well region, in accordance with some embodiments.

Since the interface IF between the emitter structure ES and the base structure BS is between the (emitter) well region 111 and the base well region B in the substrate 110, the interface IF is clean, which reduces the leakage current between the emitter structure ES and the base structure BS, in accordance with some embodiments. Therefore, the performance of the semiconductor device structure 100 is improved, in accordance with some embodiments.

Since the interface IF between the emitter structure ES and the base structure BS is between the (emitter) well region 111 and the base well region B (not between the epitaxial structures 161 and the substrate 110), the area of the interface IF can be enlarged by adjusting the sizes of the (emitter) well region 111 and the base well region B, in accordance with some embodiments. Therefore, the size (e.g., the width) of the epitaxial structures 161 may be reduced to reduce the distance between the gate stacks G11.

Since the gate stacks G11 and the epitaxial structures 161 are electrically connected to each other and are elements of the emitter structure ES, there is no leakage current between the gate stacks G11 and the epitaxial structures 161, in accordance with some embodiments. Therefore, there is no need to require a high current resistance of the gate dielectric layer 212, in accordance with some embodiments. The thickness of the gate dielectric layer 212 may be adjusted according to requirements.

Since the elements of the semiconductor device structure 100 are similar to that of the transistor, the semiconductor device structure 100 may be formed in a region of the substrate 110, which is adjacent to a transistor region (not shown) of the substrate 110, in accordance with some embodiments. The transistor region includes a logic region, in accordance with some embodiments. The semiconductor device structure 100 and transistors are formed using a transistors process, which reduces the process cost of the semiconductor device structure 100, in accordance with some embodiments. Furthermore, since the semiconductor device structure 100 is adjacent to the transistor region, the temperature sensing accuracy of temperature sensors having the semiconductor device structure 100 is improved, in accordance with some embodiments. Therefore, the power-saving efficiency of a device with the temperature sensors is improved, in accordance with some embodiments. The devices include a central processing unit (CPU) device and a graphics processing unit (GPU) device, in accordance with some embodiments.

In some embodiments, the semiconductor device structure 100 is an NPN type BJT. The substrate 110 is an N-type substrate, in accordance with some embodiments. The portion of the substrate 110, which is outside of the well regions 111 and 112, the well region 113, and the deep well region 114, has the N-type of conductivity, in accordance with some embodiments. The well regions 111 and 112 and the epitaxial structures 161 and 163 have an N-type of conductivity, in accordance with some embodiments. The deep well region 114, the well region 113, and the epitaxial structures 162 have a P-type of conductivity, in accordance with some embodiments.

The epitaxial structures 161 and 163 are made of an N-type conductivity material, in accordance with some embodiments. The N-type conductivity material includes silicon phosphorus (SiP) or another suitable N-type conductivity material. The epitaxial structures 161 and 163 are formed using an epitaxial process, in accordance with some embodiments.

The epitaxial structures 161 and 163 are doped with the Group VA element, in accordance with some embodiments. The Group VA element includes phosphor (P), antimony (Sb), or another suitable Group VA material. The epitaxial structures 161 and 163 are also referred to as doped structures, in accordance with some embodiments.

In some other embodiments, the epitaxial structures 162 are made of a P-type conductivity material, in accordance with some embodiments. The P-type conductivity material includes silicon germanium (SiGe) or another suitable P-type conductivity material. The epitaxial structures 162 are formed using an epitaxial process, in accordance with some embodiments. The epitaxial structures 162 are doped with the Group IIIA element, in accordance with some embodiments. The Group IIIA element includes boron or another suitable material.

In accordance with some embodiments, semiconductor device structures and methods for forming the same are provided. The methods (for forming the semiconductor device structure) form an emitter well region, a base well region, and a collector well region in a substrate and then perform a transistor process over the emitter well region, the base well region, and the collector well region to form an emitter structure, a base structure, and a collector structure. Since the interface between the emitter structure and the base structure is between the emitter well region and the base well region in the substrate, the interface is clean, which reduces the leakage current between the emitter structure and the base structure. Therefore, the performance of the semiconductor device structure is improved. Since the interface between the emitter structure and the base structure is between the emitter well region and the base well region (not between epitaxial structures and the substrate), the area of the interface can be enlarged by adjusting the sizes of the emitter well region and the base well region. Therefore, the size (e.g., the width) of the epitaxial structures may be reduced to reduce the distance between the gate stacks.

In accordance with some embodiments, a method for forming a semiconductor device structure is provided. The method includes forming a first well region and a second well region in a substrate. The method includes forming a third well region in the substrate and between the first well region and the second well region. The method includes forming a deep well region in the substrate and under the first well region and the third well region. The third well region and the deep well region separate the first well region from the second well region. The method includes partially removing the substrate to form a first fin, a second fin, and a third fin in the first well region, the second well region, and the third well region respectively. The method includes partially removing the first fin, the second fin, and the third fin to form a first recess, a second recess, and a third recess in the first fin, the second fin, and the third fin respectively. The method includes forming a first epitaxial structure, a second epitaxial structure, and a third epitaxial structure in the first recess, the second recess, and the third recess respectively. The first well region, the second well region, the first epitaxial structure, and the second epitaxial structure have a first type of conductivity. The deep well region, the third well region, and the third epitaxial structure have a second type of conductivity, which is different from the first type of conductivity.

In accordance with some embodiments, a method for forming a semiconductor device structure is provided. The method includes forming a first well region in a substrate. The method includes partially removing the substrate to form a first fin in the first well region. The method includes partially removing the first fin to form a first recess in the first fin. The method includes forming a first epitaxial structure in the first recess. The first well region, the first epitaxial structure, and the substrate have a first type of conductivity. The method includes forming a first gate stack over the first fin.

In accordance with some embodiments, a semiconductor device structure is provided. The semiconductor device structure includes a substrate having a first well region, a second well region, a third well region, and a deep well region. The third well region is between the first well region and the second well region, the deep well region is under the first well region and the third well region, the substrate has a first fin, a second fin, and a third fin in the first well region, the second well region, and the third well region respectively. The semiconductor device structure includes a first epitaxial structure, a second epitaxial structure, and a third epitaxial structure partially embedded in the first fin, the second fin, and the third fin respectively. The first well region, the second well region, the first epitaxial structure, and the second epitaxial structure have a first type of conductivity. The deep well region, the third well region, and the third epitaxial structure have a second type of conductivity, which is different from the first type of conductivity.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming a first well region and a second well region in a substrate;
forming a third well region in the substrate and between the first well region and the second well region;
forming a deep well region in the substrate and under the first well region and the third well region, wherein the third well region and the deep well region separate the first well region from the second well region;
partially removing the substrate to form a first fin, a second fin, and a third fin in the first well region, the second well region, and the third well region respectively;
partially removing the first fin, the second fin, and the third fin to form a first recess, a second recess, and a third recess in the first fin, the second fin, and the third fin respectively; and
forming a first epitaxial structure, a second epitaxial structure, and a third epitaxial structure in the first recess, the second recess, and the third recess respectively, wherein
the first well region, the second well region, the first epitaxial structure, and the second epitaxial structure have a first type of conductivity, and
the deep well region, the third well region, and the third epitaxial structure have a second type of conductivity, which is different from the first type of conductivity.

2. The method for forming the semiconductor device structure as claimed in claim 1, further comprising:
forming a first gate stack, a second gate stack, and a third gate stack over the first fin, the second fin, and the third fin respectively after forming the first epitaxial structure, the second epitaxial structure, and the third epitaxial structure in the first recess, the second recess, and the third recess respectively.

3. The method for forming the semiconductor device structure as claimed in claim 2, further comprising:
forming a first conductive line over the first gate stack and the first epitaxial structure, wherein the first conductive line is electrically connected to the first gate stack and the first epitaxial structure.

4. The method for forming the semiconductor device structure as claimed in claim 3, further comprising:
forming a second conductive line over the second gate stack and the second epitaxial structure, wherein the second conductive line is electrically connected to the second gate stack and the second epitaxial structure.

5. The method for forming the semiconductor device structure as claimed in claim 4, further comprising:
forming a third conductive line over the third gate stack and the third epitaxial structure, wherein the third conductive line is electrically connected to the third gate stack and the third epitaxial structure.

6. The method for forming the semiconductor device structure as claimed in claim 2, wherein the first gate stack is wrapped around an upper portion of the first fin.

7. The method for forming the semiconductor device structure as claimed in claim 1, wherein the third well region surrounds the first well region.

8. The method for forming the semiconductor device structure as claimed in claim 7, wherein the second well region surrounds the first well region and the third well region.

9. The method for forming the semiconductor device structure as claimed in claim 1, wherein the third well region and the deep well region together form a base well region, and the base well region has a U-like shape in a cross-sectional view of the third well region and the deep well region.

10. The method for forming the semiconductor device structure as claimed in claim 1, wherein a portion of the substrate, which is outside of the first well region, the second well region, the third well region, and the deep well region, has the first type of conductivity.

11. The method for forming the semiconductor device structure as claimed in claim 1, wherein the forming of the deep well region in the substrate and under the first well region and the third well region comprises:
forming a mask layer over the substrate, wherein the mask layer has an opening exposing the first well region and the third well region;
performing a first implantation process over the first well region and the third well region to form the deep well region; and
performing a second implantation process over the first well region and the third well region to widen the deep well region, wherein a first implantation direction of the first implantation process is different from a second implantation direction of the second implantation process.

12. A method for forming a semiconductor device structure, comprising:
forming a first well region in a substrate;
partially removing the substrate to form a first fin in the first well region;
partially removing the first fin to form a first recess in the first fin;
forming a first epitaxial structure in the first recess, wherein the first well region, the first epitaxial structure, and the substrate have a first type of conductivity; and
forming a first gate stack over the first fin.

13. The method for forming the semiconductor device structure as claimed in claim 12, further comprising:
forming a first conductive line over the first gate stack and the first epitaxial structure, wherein the first conductive line is electrically connected to the first gate stack and the first epitaxial structure.

14. The method for forming the semiconductor device structure as claimed in claim 13, further comprising:
forming a second well region in the substrate during forming the first well region in a substrate;
partially removing the substrate to form a second fin in the second well region during partially removing the substrate to form a first fin in the first well region;
partially removing the second fin to form a second recess in the second fin during partially removing the first fin to form the first recess in the first fin;
forming a second epitaxial structure in the second recess during forming the first epitaxial structure in the first recess, wherein the second well region and the second epitaxial structure have a second type of conductivity, which is different from the first type of conductivity; and
forming a second gate stack over the second fin during forming the first gate stack over the first fin.

15. The method for forming the semiconductor device structure as claimed in claim 14, further comprising:
forming a second conductive line over the second gate stack and the second epitaxial structure, wherein the second conductive line is electrically connected to the second gate stack and the second epitaxial structure.

16. The method for forming the semiconductor device structure as claimed in claim 15, wherein the second conductive line is grounded.

17. A semiconductor device structure, comprising:
a substrate having a first well region, a second well region, a third well region, and a deep well region, wherein the third well region is between the first well region and the second well region, the deep well region is under the first well region and the third well region, the substrate has a first fin, a second fin, and a third fin in the first well region, the second well region, and the third well region respectively; and
a first epitaxial structure, a second epitaxial structure, and a third epitaxial structure partially embedded in the first fin, the second fin, and the third fin respectively, wherein
the first well region, the second well region, the first epitaxial structure, and the second epitaxial structure have a first type of conductivity, and
the deep well region, the third well region, and the third epitaxial structure have a second type of conductivity, which is different from the first type of conductivity.

18. The semiconductor device structure as claimed in claim 17, wherein the third well region surrounds the first well region.

19. The semiconductor device structure as claimed in claim 18, wherein the second well region surrounds the third well region.

20. The semiconductor device structure as claimed in claim 17, further comprising:
a first gate stack, a second gate stack, and a third gate stack over the first fin, the second fin, and the third fin respectively.
